(19) United States
(12) Patent Application Publication
(10) Pub. No.: US 2014/0080302 A1
(43) Pub. Date: Mar. 20, 2014

(54) METHODS OF MANUFACTURING A SEMICONDUCTOR DEVICE

(71) Applicant: Samsung Electronics Co., Ltd., Suwon-Si (KR)

(72) Inventors: Tsukasa MATSUDA, Seongnam-si (KR); Jinnam KIM, Anyang-si (KR); Jongho YUN, Suwon-si (KR); Jongmyeong LEE, Seongnam-si (KR)

(73) Assignee: Samsung Electronics Co., Ltd., Suwon-Si (KR)

(21) Appl. No.: 13/966,345

(22) Filed: Aug. 14, 2013

(30) Foreign Application Priority Data
Sep. 19, 2012 (KR) 10-2012-0104109

(51) Int. Cl. H01L 21/768

(52) U.S. Cl. CPC H01L 21/76883
USPC 438/660

(57) ABSTRACT

A method of manufacturing a semiconductor device including forming a first sacrificial layer on a substrate, the first sacrificial layer including a conductive material, forming a second sacrificial layer on the first sacrificial layer, the second sacrificial layer including an insulating material, patterning the second sacrificial layer and the first sacrificial layer to form an opening successively penetrating the second and first sacrificial layers, conformally forming a seed layer on the second and first sacrificial layers including the opening, and forming a conductive pattern filling the opening having the seed layer by a plating process.

### CROSS-REFERENCE TO RELATED APPLICATIONS

This U.S. non-provisional patent application claims priority under 35 U.S.C. §119 to Korean Patent Application No. 10-2012-0104109, filed on Sep. 19, 2012, the entirety of which is incorporated by reference herein.

### BACKGROUND

1. Field

Example embodiments relate to methods of manufacturing a semiconductor device and, more particularly, to methods of manufacturing a semiconductor device including a conductive material filling an opening (e.g., a contact hole).

2. Description of the Related Art

Semiconductor devices have been highly integrated with the development of the electronic industry. Thus, various problems (e.g., process margin reduction of an exposure process defining fine patterns) occur, such that realizing semiconductor devices becomes more difficult. Additionally, higher speed semiconductor devices have also been demanded with the development of the electronic industry. Various research has been conducted for realizing highly integrated and/or higher speed semiconductor devices.

### SUMMARY

Example embodiments provide methods of manufacturing a highly integrated semiconductor device.

According to example embodiments, a method of manufacturing a semiconductor device may include forming a first sacrificial layer on a substrate, the first sacrificial layer including a conductive material, forming a second sacrificial layer on the first sacrificial layer, the second sacrificial layer including an insulating material, patterning the second sacrificial layer and the first sacrificial layer to form an opening successively penetrating the second and first sacrificial layers, conformally forming a seed layer on the second and first sacrificial layers including the opening, and forming a conductive pattern filling the opening having the seed layer by a plating process.

In example embodiments, the first sacrificial layer may function as a path through which electrons are supplied during the plating process. In example embodiments, the method may further include removing the second and first sacrificial layers. In example embodiments, the second and first sacrificial layers may be selectively removed using at least one of an oxygen (O₂) plasma etching process and an ozone (O₃) annealing etching process.

In example embodiments, the conductive pattern may be a plurality of conductive patterns, and the method may further include forming an insulating layer on the plurality of conductive patterns and the substrate after removing the second and first sacrificial layers. In example embodiments, the plurality of conductive patterns may be insulated from each other by the insulating layer.

In example embodiments, the method may further include forming an etch stop layer on the substrate before forming the first sacrificial layer. In example embodiments, the method may further include forming a capping layer on the conductive pattern. In example embodiments, the method may further include conformally forming a barrier layer on the second and first sacrificial layers having the opening before forming the seed layer.

In example embodiments, the method may further include annealing the conductive pattern. In example embodiments, the plating process may include one of an electroplating process and an electro-less plating process.

According to example embodiments, a method of manufacturing a semiconductor device may include forming at least one sacrificial layer on a substrate, the at least one sacrificial layer including a conductive material, patterning the at least one sacrificial layer to form an opening penetrating the at least one sacrificial layer, and forming a conductive pattern filling the opening by a plating process.

In example embodiments, the first sacrificial layer may function as a path through which electrons are supplied during the plating process. In example embodiments, forming at least one sacrificial layer may include forming a first sacrificial layer on a substrate, the first sacrificial layer including the conductive material, and forming a second sacrificial layer on the first sacrificial layer, the second sacrificial layer including an insulating material.

In example embodiments, the method may further include removing the at least one sacrificial layer. In example embodiments, the at least one sacrificial layer may be selectively removed using at least one of an oxygen (O₂) plasma etching process and an ozone (O₃) annealing etching process.

In example embodiments, the conductive pattern may be a plurality of conductive patterns, and the method may further include forming an insulating layer on the plurality of conductive patterns and the substrate after removing the at least one sacrificial layer. In example embodiments, the method may further include conformally forming a seed layer on the at least one sacrificial layer including the opening. In example embodiments, the plating process may include one of an electroplating process and an electro-less plating process. In example embodiments, the method may include forming an etch stop layer on the substrate before the forming at least one sacrificial layer.

### BRIEF DESCRIPTION OF THE DRAWINGS

The inventive concepts will become more apparent in view of the attached drawings and accompanying detailed description.

FIGS. 1A through 1I are cross-sectional views illustrating a method of manufacturing a semiconductor device according to example embodiments;

FIG. 2A is a schematic block diagram illustrating a memory card including a semiconductor device according to example embodiments; and

FIG. 2B is a schematic block diagram illustrating an information processing system including a semiconductor device according to example embodiments.

### DETAILED DESCRIPTION OF EXAMPLE EMBODIMENTS

The inventive concepts will now be described more fully hereinafter with reference to the accompanying drawings, in which example embodiments are shown. The advantages and features of the inventive concepts and methods of achieving them will be apparent from the following example embodiments that will be described in more detail with reference to the accompanying drawings. It should be noted, however, that the inventive concepts are not limited to the following example embodiments, and may be implemented in various forms. Accordingly, example embodiments are provided only to disclose the inventive concepts and let those skilled in the art know the category of the inventive concepts. In the drawings, example embodiments are not limited to the specific examples provided herein and are exaggerated for clarity.

The terminology used herein is for the purpose of describing particular embodiments only and is not intended to limit the inventive concepts. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, example embodiments in the detailed description will be described with sectional views as example views of the inventive concepts. Accordingly, shapes of the exemplary views may be modified according to manufacturing techniques and/or allowable errors. Therefore, example embodiments are not limited to the specific shape illustrated in the exemplary views, but may include other shapes that may be created according to manufacturing processes. Areas illustrated in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the inventive concepts. Example embodiments explained and illustrated herein include their complementary counterparts. The same reference numerals or the same reference designators denote the same elements throughout the specification.

Moreover, example embodiments are described herein with reference to cross-sectional illustrations and/or plane illustrations that are example illustrations. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

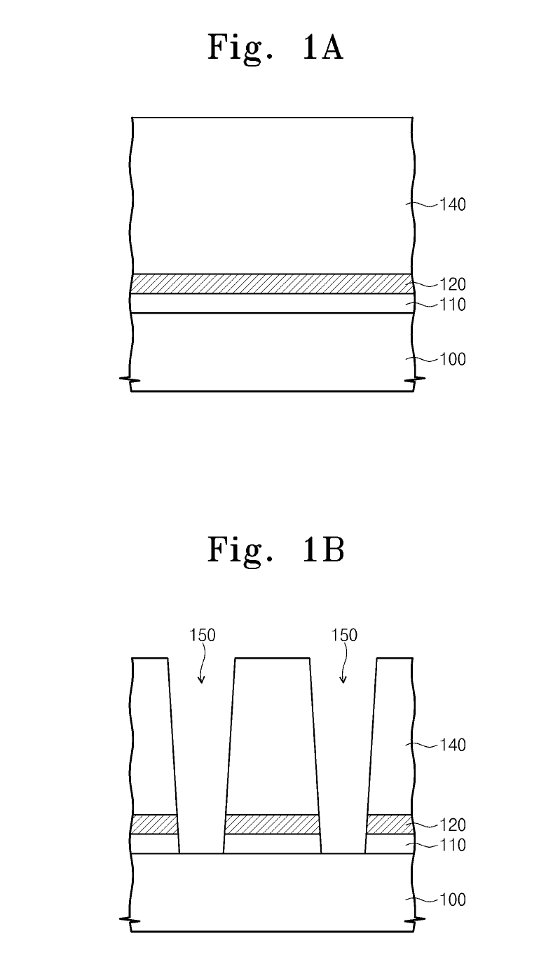

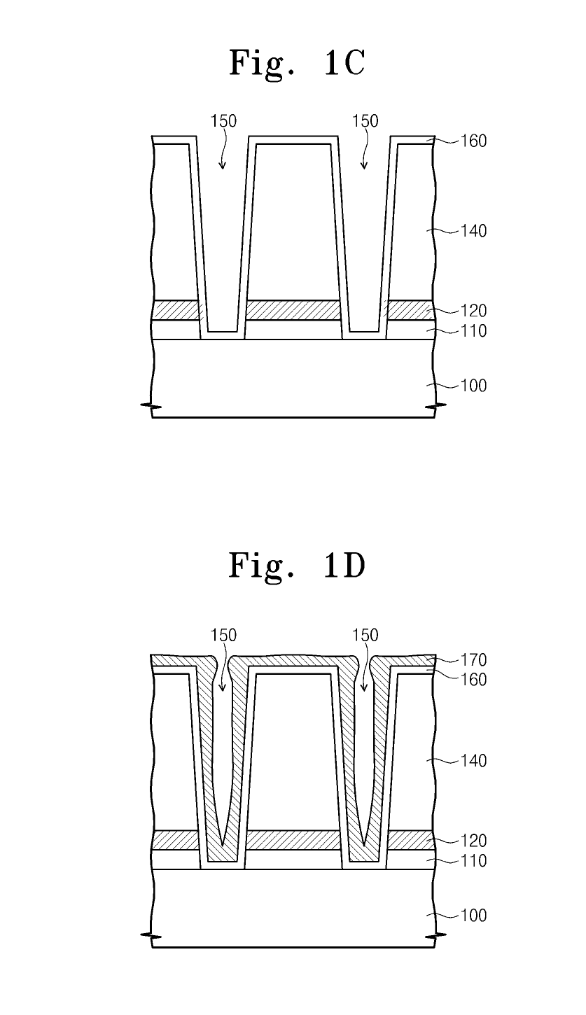

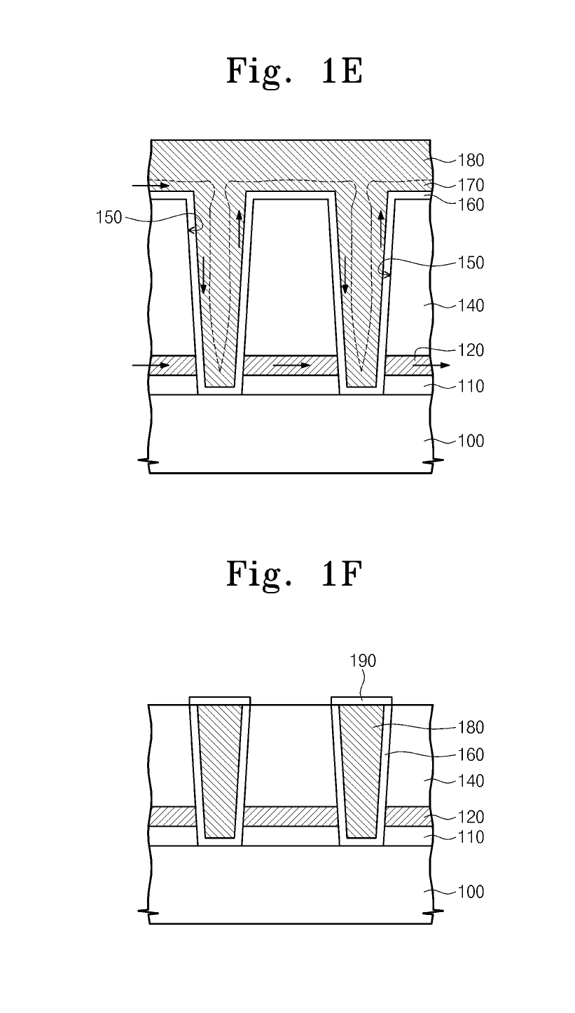

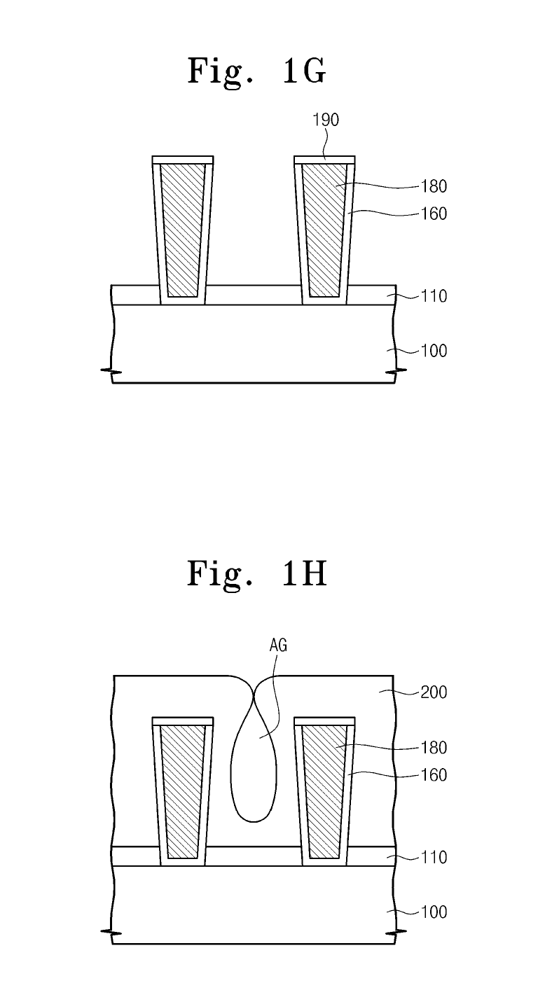

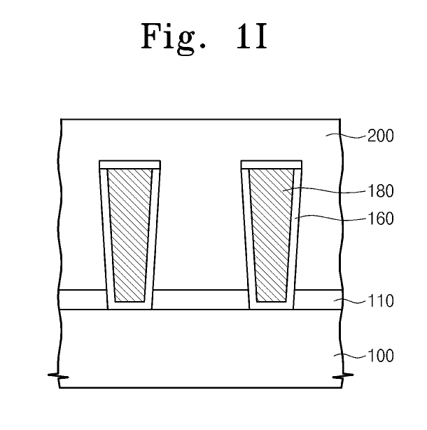

FIGS. 1A through 1I are cross-sectional views illustrating a method of manufacturing a semiconductor device according to example embodiments.

Referring to FIG. 1A, an etch stop layer 110, a first sacrificial layer 120, and a second sacrificial layer 140 may be sequentially formed on a substrate 100.

In example embodiments, a conductive pattern (not illustrated) may be formed on the substrate 100. The conductive pattern may be covered by an insulating layer. In example embodiments, the etch stop layer 110 may be formed on the insulating layer. The conductive pattern may be a source/drain region of a transistor or a contact plug.

The etch stop layer 110 may include an insulating material having an etch selectivity with respect to the substrate 100 when the etch stop layer 110 and the substrate 100 are exposed by an etchant. For example, if the substrate 100 includes a semiconductor (e.g., silicon), the etch stop layer 110 may include a nitride (e.g., silicon nitride (SiN)).

According to example embodiments, the first sacrificial layer 120 may include a conductive material. For example, the first sacrificial layer 120 may include at least one of a metal (e.g., tungsten (W) or ruthenium (Ru)) or a metal compound (e.g., ruthenium oxide (RuO₂)). The first sacrificial layer 120 may be formed by a physical vapor deposition (PVD) process, a chemical vapor deposition (CVD) process, and/or an atomic layer deposition (ALD) process.

According to example embodiments, the second sacrificial layer 140 may include an insulating material. For example, the second sacrificial layer 140 may include an oxide (e.g., silicon oxide).

In example embodiments, a thickness of the first sacrificial layer 120 may be less than a thickness of the second sacrificial layer 140.

Referring to FIG. 1B, the second sacrificial layer 140, the first sacrificial layer 120, and the etch stop layer 110 may be patterned to form openings 150 exposing the substrate 100. The patterning process may include a photolithography process and an etching process.

In example embodiments, the opening 150 may have a hole-shape or a line-shape extending in one direction.

Referring to FIG. 1C, a barrier layer 160 may be conformally formed on the sacrificial layers 140 and 120 and the etch stop layer 110 in which the openings 150 are formed. The barrier layer 160 does not fully fill the opening 150. In other words, the barrier layer 160 may conformally extend along an inner surface of the opening 150.

The barrier layer 160 may include at least one of tantalum (Ta), tantalum nitride (TaN), titanium (Ti), titanium nitride (TiN), ruthenium (Ru), or cobalt (Co). The barrier layer 160 may be formed by a PVD process, a CVD process, and/or an ALD process.

Referring to FIG. 1D, a seed layer 170 may be conformally formed on the barrier layer 160. The seed layer 170 does not fully fill the opening 150. In other words, the seed layer 170 may partially fill the opening 150.

A material of the seed layer 170 may be determined depending on a conductive material filling the opening 150 in a subsequent process. In example embodiments, if the conductive material filling the opening 150 in the subsequent process is copper (Cu), the seed layer 170 may include copper (Cu). The seed layer 170 may be formed by a PVD process, a CVD process, and/or an ALD process.

Referring to FIG. 1E, a conductive pattern 180 may be formed to fill the opening 150 by a plating process. In example embodiments, the conductive pattern 180 may include copper (Cu).

In example embodiments, the plating process may be an electroplating process. For example, the substrate 100 including the opening 150 successively penetrating the first and second sacrificial layers 140 and 120 and the etch stop layer 110 may be immersed in a solution including copper ions (Cu²⁺). Electrons may be supplied through the seed layer 170 from an external system, and the copper ions may be reduced to copper by the electrons. Thus, the opening 150 may be filled with copper. At this time, the first sacrificial layer 120 formed of the conductive material may also function as a path through which electrons are supplied. Thus, the electrons are supplied through the first sacrificial layer 120 and the seed layer 170, such that the conductive pattern 180 may completely fill the opening 170 having a relatively high aspect ratio without a void and/or a seam.

In example embodiments, the plating process may be an electro-less plating process. For example, the substrate 100 including the opening 150 penetrating the first and second sacrificial layers 120 and 140 and the etch stop layer 110 may be immersed in a solution including copper ions (Cu²⁺) and a reducing agent. The reducing agent in the solution may be oxidized to release electrons, and the electrons may reduce the copper ions through the seed layer 170. Thus, the conductive pattern 180 may be formed to fill the openings 150.

In example embodiments, the conductive pattern 180 may function as a contact plug or an interconnection. In example embodiments, the conductive pattern 180 may be annealed, such that copper grains of the conductive pattern 180 may be stabilized.

Referring to FIG. 1F, the conductive pattern 180 may be planarized until a top surface of the second sacrificial layer 140 is exposed. Subsequently, a capping layer 190 may be formed on the planarized conductive pattern 180 confined in the opening 150. The capping layer 190 may include at least one of cobalt (Co), a cobalt alloy, ruthenium (Ru), or a ruthenium alloy.

Referring to FIG. 1G, the first and second sacrificial layers 120 and 140 may be removed. The first and second sacrificial layers 120 and 140 may be removed using an etching process selectively removing the sacrificial layers 120 and 140. For example, the first and second sacrificial layers 120 and 140 may be removed by an oxygen (O₂) plasma etching process and/or ozone (O₃) annealing etching process.

In example embodiments, if a plurality of conductive patterns 180 are formed on the substrate 100, an air gap AG may be formed between the conductive patterns 180 by an insulating layer 200 after the first and second sacrificial layers are removed, as illustrated in FIG. 1H. In example embodiments, the air gap AG may insulate the conductive patterns 180 from each other.

In example embodiments, the insulating layer 200 may completely fill a space between the conductive patterns 180 as illustrated in FIG. 1I. In example embodiments, the conductive patterns 180 may be insulated from each other by the insulating layer 200.

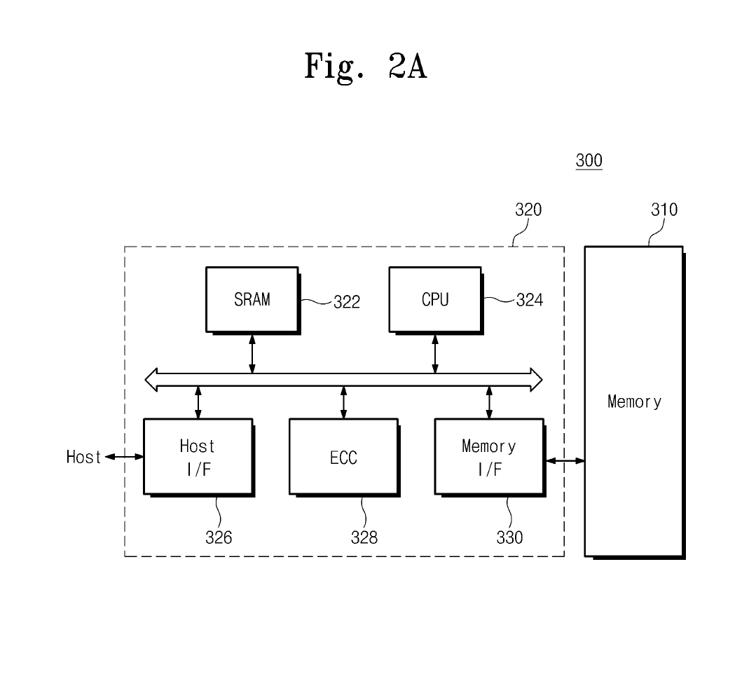

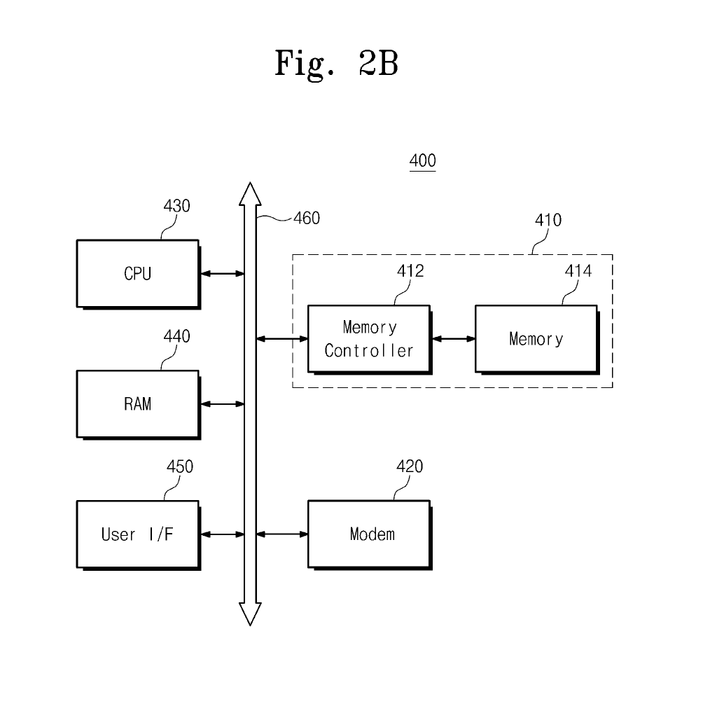

FIG. 2A is a schematic block diagram illustrating a memory card including a semiconductor device according to example embodiments.

Referring to FIG. 2A, the semiconductor device according to the aforementioned embodiments may be applied to a memory card 300. In example embodiments, the memory card 300 may include a memory controller 320 that controls data communication between a host and a memory device 310. A static random access memory (SRAM) device 322 may be used as an operation memory of a central processing unit (CPU) 324. A host interface unit 326 may be configured to include a data communication protocol between the memory card 300 and the host. An error check and correction (ECC) block 328 may detect and correct errors of data which are read out from the memory device 310. A memory interface unit 330 may interface the memory device 310. The CPU 324 controls overall operations of the memory controller 324.

The memory device 310 in the memory card 300 may include the semiconductor device according to example embodiments mentioned above. As described above, the conductive pattern of the semiconductor device may not include a void or a seam. Thus, reliability of the semiconductor device may be improved, such that reliability of the memory card may also be improved.

FIG. 2B is a schematic block diagram illustrating an information processing system including a semiconductor device according to example embodiments.

Referring to FIG. 2B, an information processing system 400 may include the semiconductor device according to example embodiments. The information processing system 400 may include a mobile device or a computer. For example, the information processing system 400 may include a modem 420, a central processing unit (CPU) 430, a random access memory (RAM) 440, and a user interface unit 450 that are electrically connected to a memory system 410 through a system bus 460. The memory system 410 may store data processed by the central processing unit 430 or data inputted from an external device. The memory system 410 may include a memory device 412 and a memory controller 414.

The memory system 410 may be substantially the same as the memory card 300 described with reference to FIG. 2A. The information processing system 400 may be realized as a memory card, a solid state disk (SSD) device, a camera image sensor and another type of application chipset. For example, the memory system 410 may be realized as the SSD device. In example embodiments, the information processing system 400 may stably and reliably store massive data.

According to example embodiments, the conductive sacrificial layer (e.g., the first sacrificial layer) is used as an electrical path during the plating process. Thus, prevention or reduction of the void or the seam from occurring within the conductive pattern formed by the plating process may be possible. Thus, electrical reliability of the semiconductor device including the conductive pattern may be improved.

While the inventive concepts have been described with reference to example embodiments, it will be apparent to those skilled in the art that various changes and modifications may be made without departing from the spirit and scope of the inventive concepts. Therefore, it should be understood that the above embodiments are not limiting, but illustrative. Thus, the scope of the inventive concepts is to be determined by the broadest permissible interpretation of the following claims and their equivalents, and shall not be restricted or limited by the foregoing description.

What is claimed is:

1. A method of manufacturing a semiconductor device, the method comprising:
forming a first sacrificial layer on a substrate, the first sacrificial layer including a conductive material;
forming a second sacrificial layer on the first sacrificial layer, the second sacrificial layer including an insulating material;
patterning the second sacrificial layer and the first sacrificial layer to form an opening successively penetrating the second and first sacrificial layers;
conformally forming a seed layer on the second and first sacrificial layers including the opening; and
forming a conductive pattern filling the opening having the seed layer by a plating process.

2. The method of claim 1, wherein the first sacrificial layer functions as a path through which electrons are supplied during the plating process.

3. The method of claim 1, further comprising:
removing the second and first sacrificial layers.

4. The method of claim 3, wherein the removing the second and first sacrificial layers selectively removes the second and first sacrificial layers using at least one of an oxygen (O₂) plasma etching process and an ozone (O₃) annealing etching process.

5. The method of claim 3, wherein the conductive pattern is a plurality of conductive patterns, further comprising:
Forming an insulating layer on the plurality of conductive patterns and the substrate after the removing the second and first sacrificial layers.

6. The method of claim 5, wherein the plurality of conductive patterns are insulated from each other by the insulating layer.

7. The method of claim 1, further comprising:
forming an etch stop layer on the substrate before the forming a first sacrificial layer.

8. The method of claim 1, further comprising:
forming a capping layer on the conductive pattern.

9. The method of claim 1, further comprising:
conformally forming a barrier layer on the second and first sacrificial layers including the opening before the conformally forming a seed layer.

10. The method of claim 1, further comprising:
annealing the conductive pattern.

11. The method of claim 1, wherein the plating process includes one of an electroplating process and an electro-less plating process.

12. A method of manufacturing a semiconductor device, the method comprising:
forming at least one sacrificial layer on a substrate, the at least one sacrificial layer including a conductive material;
patterning the at least one sacrificial layer to form an opening penetrating the at least one sacrificial layer; and
forming a conductive pattern filling the opening by a plating process.

13. The method of claim 12, wherein the first sacrificial layer functions as a path through which electrons are supplied during the plating process.

14. The method of claim 12, wherein the forming at least one sacrificial layer comprises:
forming a first sacrificial layer on a substrate, the first sacrificial layer including the conductive material; and
forming a second sacrificial layer on the first sacrificial layer, the second sacrificial layer including an insulating material.

15. The method of claim 12, further comprising:
removing the at least one sacrificial layer.

16. The method of claim 15, wherein the removing the at least one sacrificial layer selectively removes the at least one sacrificial layer using at least one of an oxygen (O₂) plasma etching process and an ozone (O₃) annealing etching process.

17. The method of claim 15, wherein the conductive pattern is a plurality of conductive patterns, further comprising:
forming an insulating layer on the plurality of conductive patterns and the substrate after the removing the at least one sacrificial layer.

18. The method of claim 12, further comprising:
conformally forming a seed layer on the at least one sacrificial layer including the opening.

19. The method of claim 12, wherein the plating process includes one of an electroplating process and an electro-less plating process.

20. The method of claim 12, further comprising:
forming an etch stop layer on the substrate before the forming at least one sacrificial layer.
